(19) United States
(12) Patent Application Publication
(10) Pub. No.: US 2018/0128153 A1
(43) Pub. Date: May 10, 2018

(54) COOLING FAN USING SURFACE COOLING EFFECT FOR ROTATING FAN BLADE PART

(71) Applicant: BRIGHTRON CO., LTD, Seoul (KR)

(72) Inventors: Sung-Bok SHIN, Gyeonggi-do (KR); Shinho KIM, Chungcheongbuk-do (KR)

(21) Appl. No.: 15/575,576

(22) PCT Filed: May 23, 2016
(86) PCT No.: PCT/KR2016/005455

§ 371 Date: Nov. 20, 2017

(30) Foreign Application Priority Data
May 21, 2015 (KR) 10-2015-0071078
Jul. 16, 2015 (KR) 10-2015-0100771

(51) Int. Cl. F01P 5/04; F01P 5/06; F25D 17/08; H02K 7/14; H05K 7/20; H01L 23/467

(52) U.S. Cl. CPC F01P 5/04; F01P 5/06; F25D 17/08; F28F 2250/08; H05K 7/20145; H01L 23/467; H02K 7/14

(57) ABSTRACT

The present invention relates to a cooling fan including a cooling device that directly transfers heat from a heat source to a rotating fan blade and implements direct cooling by a convective contact between a surface of a rotating fan blade and air in the atmosphere, without fixed heat dissipating fins. The present invention relates to a cooling fan using a surface cooling effect for a rotating fan blade part, including: a heat source part; a heat dissipating plate part installed on the heat source part; a coolant circulating pipe part for moving a coolant in a heat dissipating plate when the heat dissipating plate part uses the coolant to dissipate heat; a rotating fan blade part configured at a position at which the coolant flows in order to forcibly cool the coolant; and a driving part for rotating the rotating fan blade part.

### TECHNICAL FIELD

The present invention relates to a cooling device that can be used for heat dissipation of an automobile engine, an LED, a computer chip and the like.

More specifically, the present invention relates to a cooling fan that uses cooling through a fan blade without a fixed heat dissipating plate set in order to be able to improve cooling performance and be implemented at a compact size.

### BACKGROUND ART

Generally, a configuration of a cooling device except for a water-cooled type is largely configured to include a fixed dissipating fin set 2 connected to a heat source part as a heat source 1 and a rotating fan 4 for supplying air convection to the heat dissipating fin set.

The heat dissipating fin set 2 is configured to have a surface area as large as possible by combining a plurality of individual heat dissipating fins using a material having high thermal conductivity such as copper and aluminum.

The heat dissipating fin set 2 may be fastened through a coolant circulating pipe 3 connected from the heat source 1.

Meanwhile, the rotating fan 4 is an independent device separate from the heat dissipating fin set 2, and is attached to an upper end or a side surface of the heat dissipating fin to supply air to the heat dissipating fin 2, so heat from a base plate for the heat source is emitted to the atmosphere through the heat dissipating fin 2.

However, in such a configuration, the air generated in the rotating fan 4 can not be completely transferred to an interior due to air resistance based on the configuration of the heat radiation fin, and some air generated in the rotating fan leaks without being involved in cooling.

In addition, dust and the like are stuck in the fixedly formed heat dissipating fin 2 over time, so the heat dissipating fin 2 may have the reduced heat dissipation efficiency and may be bulky as compared with the efficiency.

### RELATED ART DOCUMENT

1. Korean Patent Laid-Open Publication No. 10-2015-0071953 (Jun. 29, 2015)

2. Korean Patent Laid-Open Publication No. 10-2015-0063949 (Jun. 10, 2015)

3. Korean Patent Laid-Open Publication No. 10-2014-0138686 (Dec. 4, 2014)

### DISCLOSURE

### Technical Problem

The present invention has been made in order to solve the above problems, and it is an object of the present invention to provide a cooling fan that is configured to directly transfer heat from a heat source to a rotating fan blade part 400 and implement directly cooling by a convective contact between a surface of the rotating fan blade part and air in the atmosphere, without the fixed heat dissipating fin set, thereby improving cooling performance.

### Technical Solution

The present invention relates to a cooling fan including a cooling device that transfers heat directly from a heat source to a rotating fan blade without a fixed heat dissipating fin and implements direct cooling by a convective contact between a surface of the rotating fan blade and air in the atmosphere, and has the following configuration in order to solve the problem.

The cooling fan includes a heat dissipating plate part 200 installed on a heat source part 100.

The heat dissipating plate part dissipates heat with a coolant, and a rotating fan blade part 400 is installed at a position at which the coolant flows in order to forcibly cool the coolant through a coolant circulating pipe part 300 through which the coolant of the heat dissipating plate part 200 moves.

The cooling fan includes a driving part for rotating the rotating fan blade part 400 to cool the coolant.

The circulating pipe part 300 used as a passage through which the coolant circulates is divided into two parts, and is configured to include a first circulating pipe 310 that is installed at a position at which the coolant is drawn out from the heat source part 100 and a second circulating pipe 320 that is installed at a position at which the coolant is introduced into the heat source part.

In addition, the rotating fan blade part 400 shows an effect by being configured alone, but is configured to include a rotating fan blade 420 and a rotating fan body 410 at a bottom portion of the rotating fan blade for better effect.

Preferably, the cooling fan is configured to include: the rotating fan body rotating while being connected to a first rotary shaft 540 that rotates while being connected to a rotating body of the driving part;

the rotating fan blade connected to the rotating fan body;

a second rotary shaft rotating while being connected to the rotating fan body.

In addition, the cooling fan is configured to include the second circulating pipe for connecting the second rotary shaft with the heat dissipation plate part.

In addition, the first and second rotary shafts are configured as a hollow pipe and are configured to transfer heat transferred from the coolant to the rotating fan blade part, and the rotating fan body and the rotating fan blade are made of a material having a heat transfer coefficient of 1 W/mK or more to facilitate heat dissipation.

In addition, the heat dissipating plate part is provided with an irregular fin to maximize a surface area, and configures a heat dissipating plate sealing cover when the heat dissipating plate part is connected with the first and second circulating pipes.

In addition, one side of the heat dissipating plate part is in contact with the heat source part and the other side of the heat dissipating plate part is in contact with the coolant.

The rotating fan blade part is configured to generate air convection in vertical and lateral directions, and the rotating fan blade part has one or more cooling fin provided on a surface thereof and is configured to guide the air convection in a predetermined direction.

The coolant is mixed with a thermally conductive contact medium to smooth a heat transfer, and the thermally conductive contact medium is selected from any one of a fluidizing lubricant and a nonfreezing coolant.

The rotating fan body and the rotating fan blade are made of a material of any one or more selected from the group consisting of metals of copper, aluminum, and magnesium, an alloy, a metal compound, an organic compound, carbon, graphite, ceramic, and a heat pipe, or a composite material thereof.

Preferably, the circulating fan for the coolant is disposed under the second rotary shaft, and the circulating fan is configured to be driven by the driving part and interlocked with the second rotary shaft.

In addition, when the first and second circulating pipes are connected to the first and second rotary shafts, respectively, a coolant sealing cover is configured, and each part rotatably connected with the coolant sealing cover is provided with a sealing seal, thereby solving the problem.

In addition, a third embodiment includes a heat source part, a heat dissipating plate part installed on the heat source part, a rotating fan blade part at a position where a coolant flows to forcibly cool the coolant, and

a driving part for rotating the rotating fan blade part, and configures the rotating fan blade part, thereby solving the problem.

In addition, a coolant moving passage is provided with a bent portion to widen a surface area of the coolant to move the coolant to an end portion of a wing part of the rotating fan blade part.

Herein, a rotating fan may be separately formed inside the rotating fan blade to further widen the surface area of the coolant.

In the configuration, the rotary plate blade and the rotating fan body are integrally formed.

### Advantageous Effects

The cooling device configuration requiring heat dissipation,

has both advantages of the water cooling type and the air cooling type by directly transferring heat from the heat source to the rotating fan blade and implementing the direct cooling by the convective contact between the surface of the rotating fan blade and the air in the atmosphere, without the fixed heat dissipating fins, thereby increasing the cooling efficiency, simplifying the structure, and saving the manufacturing costs of the cooling device.

### BRIEF DESCRIPTION OF THE DRAWINGS

FIG. 1 is a perspective view of a conventional cooling device.

FIG. 2 is a cutaway perspective view of a cooling fan according to a first embodiment of the present invention.

FIG. 3 is a view showing a flow of coolant of the cooling fan according to the present invention.

FIG. 4 is a view showing that a cylindrical rotary shaft is engaged with a driving shaft and a coolant flows in a gap therebetween.

FIG. 5 is a cutaway perspective view of a cooling fan according to a second embodiment of the present invention that is integrated with the heat source part according to the present invention.

FIG. 6 is a cutaway perspective view of a cooling fan according to a third embodiment of the present invention that is integrated with the heat source part according to the present invention.

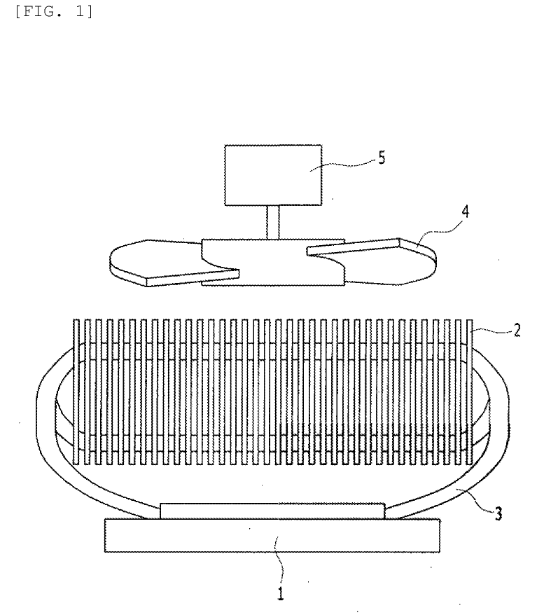

### BEST MODE

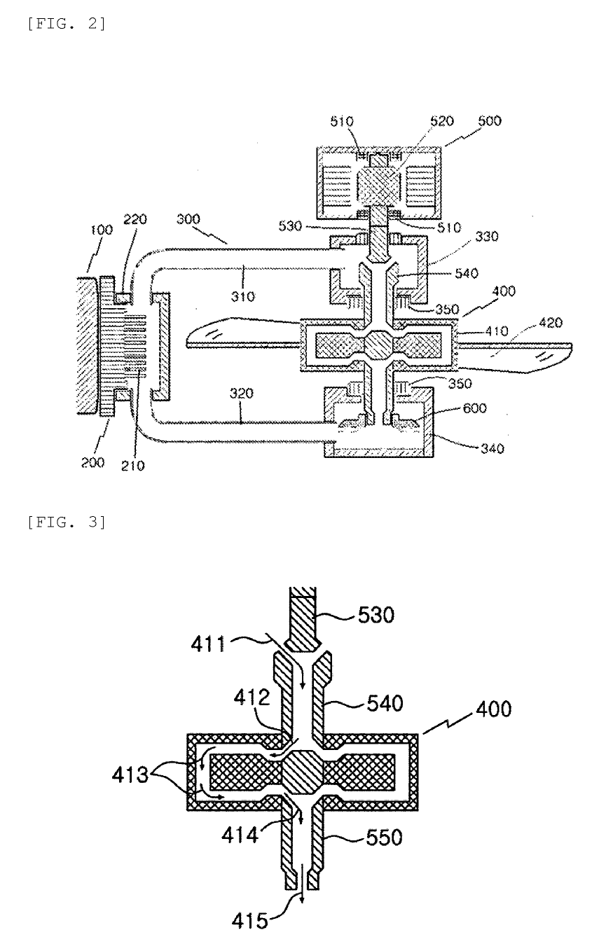

The best embodiment is a first embodiment of a detailed description of the present invention and is shown in FIG. 2.

A heat dissipating plate part 200 is installed on a heat source part 100.

The heat dissipating plate part dissipates heat with a coolant, and a rotating fan blade part 400 is installed at a position at which the coolant flows in order to forcibly cool the coolant through a coolant circulating pipe part 300 through which the coolant of the heat dissipating plate part 200 moves.

A driving part 500 rotates the rotating fan blade part 400 to cool a coolant and is formed as a motor.

The circulating pipe part 300 used as a passage through which the coolant circulates is divided into two parts and is configured to include a first circulating pipe 310 that is installed at a position at which the coolant is drawn out from the heat source part 100 and a second circulating pipe 320 that is installed at a position at which the coolant is introduced into the heat source part.

In addition, the rotating fan blade part 400 may show an effect by being configured alone, but is configured to include a rotating fan blade 420 and a rotating fan body 410 at a bottom portion of the rotating fan blade for better effect.

Preferably, the first rotary shaft 540 rotates while being connected to a motor rotary shaft 530 of the driving part, and more preferably, is formed as a hollow shaft, wherein an inside of the rotary shaft is provided with a space so that a coolant may flow in the hollow. As shown in FIG. 2, a coolant flows in an outside of the rotating fan body 410 rotating while being connected to the first rotary shaft so that a cooling effect of the coolant flowing in the rotating fan blade 420 that is connected to the rotating fan body 410 can be maximized.

### MODE FOR INVENTION

In order to achieve the above object, in a cooling fan using a surface cooling effect for a rotating fan blade itself of the present invention,

a heat dissipating fin is coupled to a wind generating rotating fan.

A detailed configuration of the first embodiment,

will be described with reference to FIG. 2.

A heat dissipating plate part 200 is installed on a heat source part 100.

The heat dissipating plate part dissipates heat with a coolant, and a rotating fan blade part 400 is installed at a position at which the coolant flows in order to forcibly cool the coolant through a coolant circulating pipe part 300 through which the coolant of the heat dissipating plate part 200 moves.

A driving part 500 rotates the rotating fan blade part 400 to cool a coolant and is formed as a motor.

In addition, the circulating pipe part 300 used as a passage through which the coolant circulates is divided into two parts and is configured to include a first circulating pipe 310 that is installed at a position at which the coolant is drawn out from the heat source part 100 and a second circulating pipe 320 that is installed at a position at which the coolant is introduced into the heat source part.

In addition, the rotating fan blade part 400 may show an effect by being configured alone, but is configured to include a rotating fan blade 420 and a rotating fan body 410 at a bottom portion of the rotating fan blade for better effect.

Preferably, the first rotary shaft 540 rotates while being connected to a motor rotary shaft 530 of the driving part, and more preferably, is formed as a hollow shaft, wherein an inside of the rotary shaft is provided with a space so that a coolant may flow in the hollow portion. As shown in FIG. 2, a coolant flows in an outside of the rotating fan body 410 rotating while being connected to the first rotary shaft so that a cooling effect of the coolant flowing in the rotating fan blade 420 that is connected to the rotating fan body 410 can be maximized.

The following description will be given with reference to FIG. 3.

In the rotating fan body 410, a coolant flows through an end portion 413 of the rotating fan body connected to the rotating fan blade 420 through a body inlet 412 of the rotating fan body 410 via a coolant inlet 411 which is an end portion of the first rotary shaft 540.

In this case, the fan inside the rotating fan body has an annular shape. When being not operated, the fan is in contact with a lower portion of the body and then when the blade is operated, the contacting rotating fan by the rotation of the blade stays at a current position of FIG. 3, thereby making a cooling effect good and smoothing a water flow.

The coolant flowing in the rotating fan body deviates from the rotating fan body and is introduced into the second rotary shaft via the hollow portion of the hollow rotary shaft (414). A second rotary shaft 550 rotating while connected to the rotating fan body 410 is provided.

A connecting part 416 to which the first and second rotary shafts 540 and 550 and the rotating fan body 410 are coupled is a sealed, and the first rotary shaft 540 has strength enough to be able to rotate the rotating fan blade part 400.

Preferably, the coolant circulating pipe part 300 is divided into two parts, and is configured to include the first circulation pipe 310 that is installed at a position at which the coolant is drawn out from the heat source part and the second circulating pipe 320 that is installed at a position at which the coolant is introduced into the heat source part.

Preferably, the rotating fan blade part 400 includes the rotating fan blade 420 and the rotating fan body 410 at the bottom of the rotating fan blade, thereby maximizing the cooling effect of the coolant.

The driving source uses a motor as the driving part 500.

The first rotary shaft 540 is connected to the rotating body 520 of the motor to rotate the rotating blade, and has a hollow portion so that the coolant flows through the hollow portion.

The second rotary shaft 550 is configured to rotate while being connected to the rotating fan body 410, and also has a hollow portion in which the coolant flows, thereby maximizing the cooling effect.

The second circulating pipe 320 is configured to connect the second rotary shaft 550 with the heat dissipating plate part 220.

As described above, the first and second rotary shafts 540 and 550 are hollow pipes, and transfer the heat transferred from the coolant to the rotating fan blade part 400. Here, the rotating fan body 410 and the rotating fan blade 420 are made of a material having a heat transfer coefficient of 1 W/mK or more to facilitate heat dissipation.

Further, the heat dissipating plate part 200 is provided with an irregular fin 210 to maximize the surface area.

A sealing cover for a heat dissipating plate is formed when the heat dissipating plate part is connected to the first and second circulating parts to prevent a coolant from leaking.

Preferably, one side of the heat dissipating plate part 200 is in contact with the heat source part 100 and the other side of the heat dissipating plate part 200 is in contact with the coolant.

The rotating fan blade part 400 is configured to generate air convection in vertical and lateral directions.

The surface of the rotating fan blade part 400 is provided with one or more cooling fin, and guides air convection in a predetermined direction.

The coolant is mixed with a thermally conductive contact medium to smooth a heat transfer, and the thermally conductive contact medium is selected from any one of a fluidizing lubricant and a nonfreezing coolant to make the heat transfer excellent.

The products of the rotating fan body and the rotating fan blade are made of a material of any one or more selected from the group consisting of metals of copper, aluminum, and magnesium, an alloy, a metal compound, an organic compound, carbon, graphite, ceramic, and a heat pipe, or are made of a complex material thereof, thereby further increasing the cooling effect.

More preferably, the circulating fan for the coolant is provided at a position at which the coolant flows.

More preferably, the circulating fan 600 is disposed under the hollow second rotary shaft 550.

The circulating fan 600 is configured to be driven by the driving part 500. The circulating fan is interlocked with the second rotary shaft and is driven by one driving source.

In order to prevent the coolant from leaking, coolant sealing covers 330 and 340 are formed when the first and second circulating pipes 310 and 320 are connected to the first and second rotary shafts 540 and 550, respectively.

A sealing seal 350 is formed at each of each part rotatably connected to the coolant sealing covers 330 and 340.

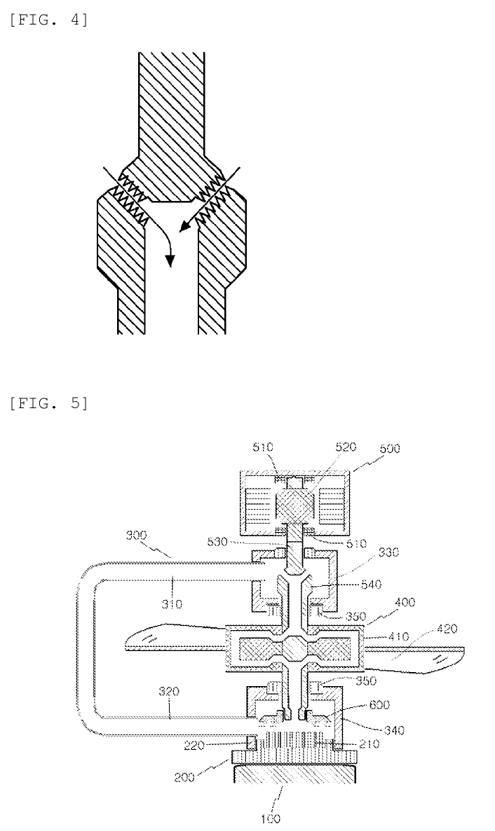

FIG. 4 shows that a toothed gear of the hollow rotating pipe is engaged with a toothed gear of the motor shaft. At this time, a pitch between the tooted gears is long or a peak of the toothed gear is deep to smooth the flow of the coolant.

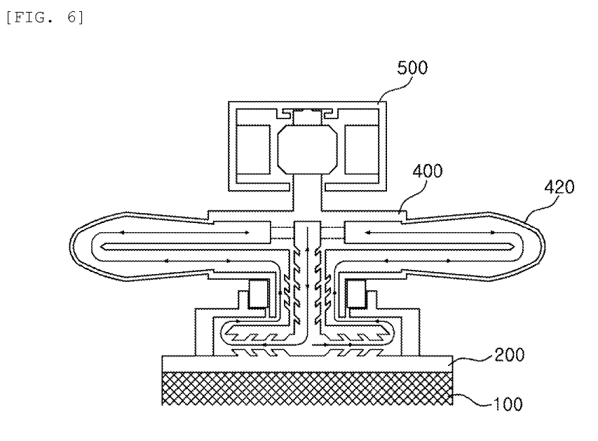

A second embodiment will be described with reference to FIG. 5.

A cooling fan includes: a heat source part 100;

a heat dissipating plate part 200 installed on the heat source part;

The heat dissipating plate part dissipates heat with a coolant, and as a coolant circulating pipe part 300 through which the coolant of the heat dissipating plate part 200 move, the first and second circulating pipes 310 and 320 according to the first embodiment are integrated and the heat source is provided just under the circulating fan.

A rotating fan blade part 400 is provided at a position at which the coolant flows to forcibly cool the coolant. Similar to the first embodiment,

as a driving part 500 for rotating the rotating fan blade part 400, a motor is provided, and a circulating fan 600 is provided near the heat source part under a second rotary shaft using the first rotary shaft 540 and the second rotary shaft 550 to rotate the rotating fan blade.

By this configuration, the heat transferred to the rotating fan blade 420 is directly dissipated in the air by a convective contact between a surface of the rotating fan blade 420 rotating by the driving part 500 and air in the atmosphere.

This concept is based on the fact that all the air transferred to the surface of the conventional dissipating fin set 2 finally flows through the rotating fan. The rotating fan blade 420 is made of metal or the like suitable for heat radiation. The heat is absorbed into the rotating fan body 410 by the circulation of coolant from the heat source part and is transferred to the rotating fan blade 420. As a result, it is possible to obtain a cooling function equal to or better than the cooling effect of the existing dissipating fin.

Here, the number of rotating fan blades 420 and the degree of inclination of the blade for forming the convection current should be appropriately adjusted.

As the blade is made of a material of low thermal conductivity, a rotating speed or a surface area should be further increased to increase the driving energy. As a result, the material of the blade is very important.

Generally, the blade of the rotating fan is made of a plastic material. In this case, it is difficult to expect the self-heat dissipation of the blade. On the other hand, the blade is often made of metal. In this case, however, it is neither intended for self-heat dissipation and is nor equipped with a means for transferring heat to the blade. Therefore, they have other object different from the constituent of the metal material for dissipating the heat according to the present invention.

In addition, the rotating fan blade part 420 is preferably configured to generate air convection in vertical and lateral directions,

However, since the rotating fan blade 420 is not for supplying air to any device, it is not necessary to form such powerful air convection.

On the other hand, the surface of the rotating fan blade 420 may be further provided with one or more cooling fin to further increase the cooling efficiency. This is different from the conventional fixed type heat dissipating fin, and it is intended to maximize the air contact surface area of the rotating blades to further facilitate the heat dissipation.

Subsequently,

the heat source part 100 may be a heating element requiring heat dissipation such as an automobile engine, an LED, a computer main CPU, and a graphic chip. The coolant heat dissipating plate 200 is tightly fixed to the heat source part 100, and an upper portion thereof is sealed with the coolant heat dissipating plate sealing cover 220 and comes into contact with the coolant within the coolant heat dissipating plate sealing cover 220. Meanwhile, the upper portion of the coolant heat dissipating plate 200 may be provided with irregular fins to increase the surface area, so the heat of the heat source part 100 can be rapidly transferred to the coolant.

FIG. 6 shows that the circulating pipe is not required and is connected to a heat source so that a coolant flows to an outermost portion of the blade to pass the coolant through a large surface area.

In order to increase the surface area of the coolant flow, various shapes may be shown as shown in FIG. 6. The direction of the arrow indicates the flow of the coolant when the blade is operated.

In the above configuration, heat is directly transferred from the heat source part to the rotating fan body that rotates through the heat transfer means, that is, the circulation of the coolant, without the heat dissipating fin and the metallic rotating fan blades coupled to the rotating fan body rotates by the rotation of the motor, thereby finally emitting heat to the atmosphere by the surface cooling effect generated by the contact with the air on the surface of the rotating fan blade. That is, the characteristic structure of the present invention is that the heat dissipating structure is formed in a rotor.

As described in detail, the cooling fan using the surface cooling effect for the rotating fan blade itself of the present invention can improve the cooling performance and make the relative size compact.

### INDUSTRIAL APPLICABILITY

The present invention provides the cooling fan that directly transfers heat from the heat source to the rotating fan blade part 400 and implements the direct cooling by the convective contact between the surface of the rotating fan blade part and the air in the atmosphere, without the fixed heat dissipating fin set, to improve the cooling performance, thereby preventing the size of the machine from becoming very large due to the cooling by the cooling device requiring the heat dissipation. As a result, the present invention has highly industrial applicability.

The present invention has both advantages of the water cooling type and the air cooling type, and has an excellent effect of increasing the cooling efficiency, simplifying the structure, and reducing the manufacturing cost of the cooling device, and has highly industrial applicability.

1. A cooling fan using a surface cooling effect for a rotating fan blade part, comprising:
a heat source part;
a heat dissipating plate part installed on the heat source part;
a coolant circulating pipe part for moving a coolant in a heat dissipating plate when the heat dissipating plate part uses the coolant to dissipate heat;
a rotating fan blade part configured at a position at which the coolant flows in order to forcibly cool the coolant; and
a driving part for rotating the rotating fan blade part.

2. The cooling fan of claim 1, wherein the coolant circulating pipe part is divided into two parts and is configured to include a first circulating pipe that is installed at a position at which the coolant is drawn out from the heat source part and a second circulating pipe that is installed at a position at which the coolant is introduced into the heat source part.

3. The cooling fan of claim 1, wherein the coolant circulating pipe part is configured into one, and the heat source part is provided just under a rotary shaft.

4. The cooling fan of claim 2, wherein the rotating fan blade part is configured to include a rotating fan blade and a rotating fan body at a bottom portion of the rotating fan blade.

5. The cooling fan of claim 3, further comprising:
a first rotary shaft rotating while being connected to a rotating body of the driving part; the rotating fan body rotating while being connected to the first rotating shaft; the rotating fan blade connected to the rotating fan body; and a second rotating shaft rotating while being connected to the rotating fan body.

6. The cooling fan of claim 4, wherein the second circulating pipe is provided to connect the second rotating shaft with the heat dissipating plate part.

7. The cooling fan of claim 1, wherein the first and second rotating shafts are a hollow pipe and end portions thereof are provided with a toothed gear.

8. (canceled)

9. The cooling fan of claim 4, wherein the rotating fan body and the rotating fan blade are made of a material having a heat transfer coefficient of 1 W/mK or more to facilitate heat dissipation.

10. The cooling fan of claim 1, where the heat dissipating plate part is provided with an irregular fin to maximize a surface area.

11. The cooling fan of claim 1, wherein a heat dissipating plate sealing cover is configured when the heat dissipating plate part is connected to the first and second circulating pipes.

12. (canceled)

13. The cooling fan of claim 1, wherein the rotating fan blade part is configured to generate an air convection in vertical and lateral directions.

14. The cooling fan of claim 1, wherein the rotating fan blade part has one or more cooling fin provided on a surface thereof and is configured to guide the air convection in a predetermined direction.

15. (canceled)

16. The cooling fan of claim 4, wherein the rotating fan body and the rotating fan blade are made of a material of any one or more selected from the group consisting of metals of copper, aluminum, and magnesium, an alloy, a metal compound, an organic compound, carbon, graphite, ceramic, and a heat pipe or a composite material thereof.

17. The cooling fan of claim 1, further comprising:
a circulating fan for the coolant.

18. The cooling fan of claim 17, wherein the circulating fan is provided under the second rotating shaft.

19. (canceled)

20. The cooling fan of claim 17, wherein the circulating fan is configured to be interlocked with the second rotating shaft.

21. (canceled)

22. (canceled)

23. The cooling fan of claim 1, wherein a circulating fan 600 is provided under a second rotating shaft using a first rotary shaft for rotating the rotating fan blade part and a second rotary shaft for rotating the circulating fan, and the heat dissipating plate part is provided near the circulating fan.

24. A cooling fan using a surface cooling effect for a rotating fan blade part, comprising:
a heat source part;
a heat dissipating plate part installed on the heat source part;
a rotating fan blade part configured at a position at which the coolant flows in order to forcibly cool the coolant; and
a driving part for rotating the rotating fan blade part.

25. The cooling fan of claim 24, wherein a coolant moving passage is provided with a bent portion to widen a surface area of the coolant to move the coolant to an end portion of a wing part of the rotating fan blade part.

26. The cooling fan of claim 24, wherein an inside of the rotating plate blade is separately provided with a rotating plate to widen a surface area of the coolant.

27. (canceled)
